(19) United States
(12) Patent Application Publication
(10) Pub. No.: US 2024/0258458 A1
(43) Pub. Date: Aug. 1, 2024

(54) MULTIJUNCTION LIGHT EMITTING DIODES

(71) Applicant: Alliance for Sustainable Energy, LLC, Golden, CO (US)

(72) Inventors: Ryan Matthew FRANCE, Golden, CO (US); Kirstin ALBERI, Denver, CO (US)

(21) Appl. No.: 18/406,697

(22) Filed: Jan. 8, 2024

Related U.S. Application Data
(60) Provisional application No. 63/482,181, filed on Jan. 30, 2023.

(51) Int. Cl. H01L 33/06; H01L 25/075; H01L 33/00; H01L 33/30

(52) U.S. Cl. CPC H01L 33/06; H01L 25/0753; H01L 33/0008; H01L 33/30

(57) ABSTRACT

The present disclosure relates to a device that includes a first stack and a second stack, with each stack including, in order: an n-type cladding layer constructed of an alloy selected from at least one of GaInP, AlGaAs, GaInAsP, and/or AlGaInP, an n-type outer barrier layer constructed of at least one of GaAs and/or GaP; at least one quantum well; a p-type outer barrier layer constructed of at least one GaAs or GaP; and a p-type cladding layer constructed an alloy selected from at least one of GaInP, AlGaAs, GaInAsP, and/or AlGaInP; and a tunnel junction.

### CROSS-REFERENCE TO RELATED APPLICATIONS

This application claims priority from U.S. Provisional Patent Application No. 63/482,181 filed on Jan. 30, 2023, the contents of which are incorporated herein by reference in the entirety.

### CONTRACTUAL ORIGIN

This invention was made with government support under Contract No. DE-AC36-08GO28308 awarded by the Department of Energy. The government has certain rights in the invention.

### BACKGROUND

LED efficiency depends on, among other things, the operating condition of the device, including the drive current and voltage. Furthermore, the impact of operating current on efficiency depends on the material system utilized and the electronic system containing the LED. Further, wide-ranging applications for LEDs results in a wide range of LED operating conditions. One common problem is the efficiency loss that can occur at high drive-currents, where power is lost due to resistive losses in addition to losses resulting from underlying material-related challenges such as Auger recombination and/or carrier confinement losses. Therefore, there remains a need for improved materials and LED device designs that can overcome these challenges.

### SUMMARY

An aspect of the present disclosure is a device that includes a tunnel junction, a first stack, and a second stack, with each stack including, in order: an n-type cladding layer constructed of an alloy selected from at least one of GaInP, AlGaAs, GaInAsP, and/or AlGaInP, an n-type outer barrier layer constructed of at least one of GaAs and/or GaP; at least one quantum well; a p-type outer barrier layer constructed of at least one GaAs or GaP; and a p-type cladding layer constructed an alloy selected from at least one of GaInP, AlGaAs, GaInAsP, and/or AlGaInP. The tunnel junction is positioned between the p-type cladding layer of the first stack and the n-type cladding layer of the second stack, the device is capable of emitting light having a wavelength between 880 nm and 1300 nm, and the tunnel junction is transparent to the emitted light.

In some embodiments of the present disclosure, the n-type outer barrier layer and p-type outer barrier layer may be constructed of GaAs. In some embodiments of the present disclosure, the n-type cladding layer may be constructed of Ga₁₋ᵥInᵥP, where 0<v<1.0. In some embodiments of the present disclosure, 0.4≤v≤0.6.

In some embodiments of the present disclosure, the n-type cladding layer may have a bandgap greater than about 1.4 eV. In some embodiments of the present disclosure, the p-type cladding layer may be constructed of Ga₁₋ᵥInᵥP, where 0≤v≤1.0. In some embodiments of the present disclosure, 0.4≤v≤0.6. In some embodiments of the present disclosure, v may be about equal to 0.5. In some embodiments of the present disclosure, the n-type cladding layer may have a bandgap greater than about 1.4 eV.

In some embodiments of the present disclosure, each quantum well may include a well layer positioned between a first barrier layer and a second barrier layer. In some embodiments of the present disclosure, for each quantum well, the well layer, the first barrier layer, and the second barrier layer may be strain-balanced. In some embodiments of the present disclosure, the number of quantum wells may be between 1 and 50 inclusively. In some embodiments of the present disclosure, each barrier layer may be constructed of GaAs_{1-w}P_{w}, where 0.01<w<0.5. In some embodiments of the resent disclosure, each well layer may be constructed of GaIn₁₋ₓAsₓ, where

$$0.01 < x < 0.4 .$$

In some embodiments of the present disclosure, the tunnel junction may include a heavily doped p-n junction. In some embodiments of the present disclosure, the tunnel junction may further include a quantum well. In some embodiments of the present disclosure, the quantum well of the tunnel junction may be constructed of GaAs. In some embodiments of the present disclosure, the p-n junction may include p-type Al_{1-y}Ga_{y}As and n-type Al_{1-y}Ga_{y}As, where 0<y<1 independently of each other. In some embodiments of the present disclosure, the device may further include at least one additional stack.

### BRIEF DESCRIPTION OF DRAWINGS

Some embodiments are illustrated in referenced figures of the drawings. It is intended that the embodiments and figures disclosed herein are to be considered illustrative rather than limiting.

FIGS. 1A, 1B, and 1C illustrate aspects of a multijunction light emitting diode (LED), according to some embodiments of the present disclosure.

FIG. 2 illustrates a 2-junction GaInAs-containing LED, according to some embodiments of the present disclosure.

FIG. 3 illustrates current-voltage characteristics of GaInAs LEDs with varied number of junctions, plotted linearly (top) to show the turn-on voltage, and logarithmically (bottom) to show that the ideality factor per junction is equivalent in all devices.

FIGS. 4A, 4B, and 4C illustrate a comparison of two cell sizes for devices with different numbers of junctions and a variety of cell sizes, according to some embodiments of the present disclosure.

FIG. 5 illustrates the electroluminescence versus wavelength for a four-junction device, according to some embodiments of the present disclosure.

### REFERENCE NUMERALS

100 . . . light emitting diode
105 . . . device stack
110 . . . substrate
120 . . . n-type layers
122 . . . n-type contact layer
124 . . . n-type cladding layer
126 . . . n-type outer barrier layer
130 . . . quantum w ell
130-1 . . . well layer
130-2 and 130-3 . . . barrier layer
140 . . . p-type layers
142 . . . p-type outer barrier layer
144 . . . p-type cladding layer
147 . . . p-type contact layer
160 . . . contact
170 . . . tunnel junction
170-1 . . . first layer
170-2 . . . second layer
170-3 . . . third layer

### DETAILED DESCRIPTION

The embodiments described herein should not necessarily be construed as limited to addressing any of the particular problems or deficiencies discussed herein. References in the specification to “one embodiment”, “an embodiment”, “an example embodiment”, “some embodiments”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

As used herein the term “substantially” is used to indicate that exact values are not necessarily attainable. By way of example, one of ordinary skill in the art will understand that in some chemical reactions 100% conversion of a reactant is possible, yet unlikely. Most of a reactant may be converted to a product and conversion of the reactant may asymptotically approach 100% conversion. So, although from a practical perspective 100% of the reactant is converted, from a technical perspective, a small and sometimes difficult to define amount remains. For this example of a chemical reactant, that amount may be relatively easily defined by the detection limits of the instrument used to test for it. However, in many cases, this amount may not be easily defined, hence the use of the term “substantially”. In some embodiments of the present invention, the term “substantially” is defined as approaching a specific numeric value or target to within 20%, 15%, 10%, 5%, or within 1% of the value or target. In further embodiments of the present invention, the term “substantially” is defined as approaching a specific numeric value or target to within 1%, 0.9%, 0.8%, 0.7%, 0.6%, 0.5%, 0.4%, 0.3%, 0.2%, or 0.1% of the value or target.

As used herein, the term “about” is used to indicate that exact values are not necessarily attainable. Therefore, the term “about” is used to indicate this uncertainty limit. In some embodiments of the present invention, the term “about” is used to indicate an uncertainty limit of less than or equal to ±20%, ±15%, ±10%, ±5%, or ±1% of a specific numeric value or target. In some embodiments of the present invention, the term “about” is used to indicate an uncertainty limit of less than or equal to 1%, 0.9%, 0.8%, ±0.7%, ±0.6%, ±0.5%, ±0.4%, ±0.3%, ±0.2%, or ±0.1% of a specific numeric value or target.

A multijunction light emitting diode (also called a cascading light emitting diode, but not to be confused with an interband cascade device) combines multiple light emitting diodes (LEDs) in tandem through the use of tunnel junctions. The result is a single device but with multiple internal light-emitting diodes. The overall goal of a multijunction LED is to increase LED efficiency and ease of system integration, particularly at high operation currents. Multijunction LEDs, where each junction has the same bandgap and emission energy, increase the operating voltage and reduce the required current for a given emission intensity. Reduced current benefits devices that suffer from resistive loss or quantum efficiency loss at high currents. Droop can occur in III-As or III-P-based LEDs under certain circumstances. For instance, operation close to the direct-indirect crossover can lead to carrier spillage, high current, and thus droop. In addition to the efficiency benefits of reducing current, the higher operating voltage also benefits low bandgap GaInAs LEDs, and As/P-based LEDs in general, by enabling easier integration into low power circuits. The operating voltage is closer matched to other system components, and the system has different impedance requirements.

Described herein is a multijunction LED made of III-P and/or III-As materials where each LED-component has nearly the same wavelength of emission. Combining multiple similar-wavelength LED-components into a multijunction LED in this way leads to an increase in the number of emitted photons for a given current, which can increase device efficiency. In theory, multijunction LEDs can also be constructed of LED-components with different wavelengths of emission, leading to a broadened emission spectrum or multi-wavelength emitters. Some embodiments of the present disclosure include GaInAs LEDs with one, two, three, four, and/or 4+ junctions. Some embodiments of these devices demonstrated quantum efficiency improvements resulting from additional junctions, and high quantum efficiencies, such as greater than 50% at 500 mA/cm² for a planar device without an antireflective coating.

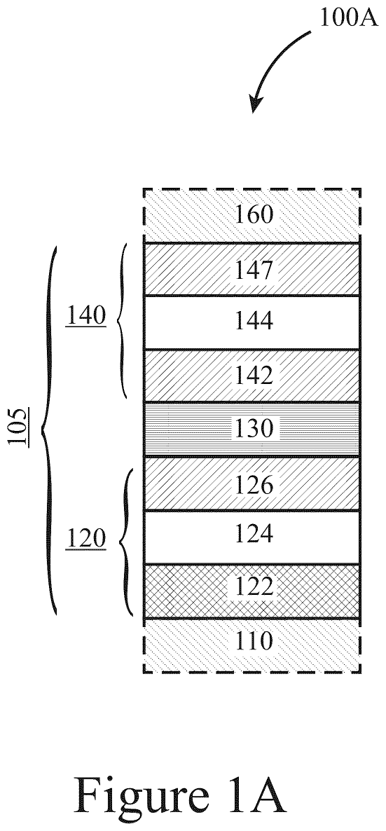

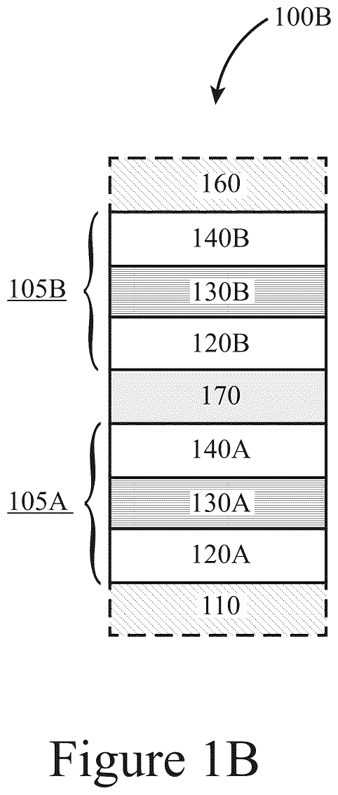

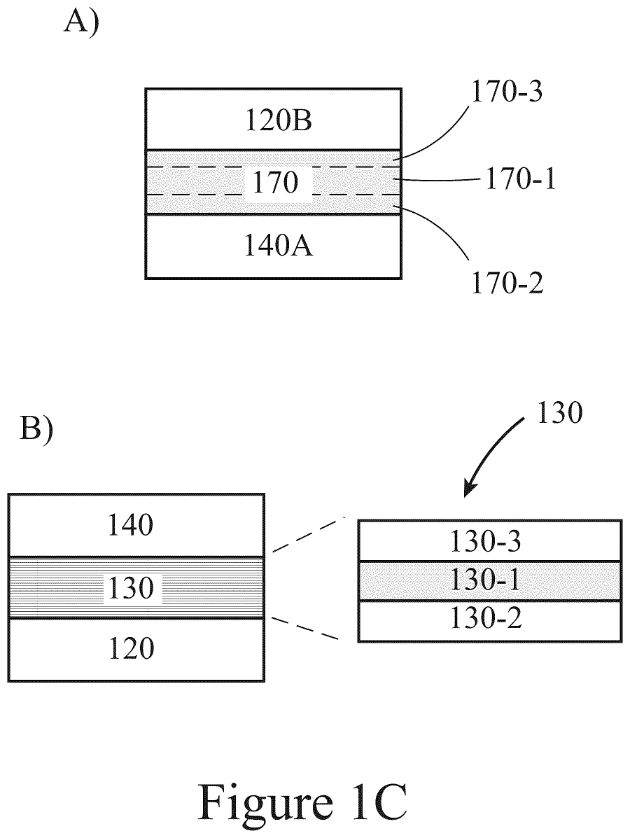

FIG. 1A illustrates a single-junction light emitting diode (LED) 100A and FIG. 1B illustrates a two-junction LED 100B, according to some embodiments of the present disclosure. Referring to FIG. 1A, a junction of an LED includes a device stack 105 positioned between a substrate 110 and a contact 160. Further, a device stack 105 may include one or more quantum wells 130 positioned between a group of n-type layers 120 and a group of p-type layers 140. As explained below, a quantum well 130 is a multilayer feature constructed of three individual layers and an LED may include multiple quantum wells stacked together in series. FIG. 1A illustrates a single-junction LED 100A, as it contains a single device stack 105, whereas FIG. 1B illustrates a two-junction LED 100B, as it contains a first device stack 105A and a second device stack 105B separated by a tunnel junction 170 positioned between the two device stacks (105A and 105B).

Referring again to FIG. 1A, in some embodiments of the present disclosure, a group of n-type layers 120 may include an n-type cladding layer 124 positioned between an n-type contact layer 122 and an n-type active layer 126, where the n-type outer barrier layer 126 is positioned between one or more quantum wells 130 and the n-type cladding layer 124 and the n-type contact layer 122 are positioned between the substrate 110 and the n-type cladding layer 124. Similarly, in some embodiments of the present disclosure a group of p-type layers 140 may include an p-type cladding layer 144 positioned between an p-type contact layer 147 and an p-type outer barrier layer 142, where the p-type outer barrier layer 142 is positioned between the one or more quantum wells 130 and the p-type cladding layer 144 and the p-type contact layer 147 are positioned between the contact 160 and the p-type cladding layer 144. Referring again to FIG. 1A, the exemplary LED 100A is illustrated with the n-type layers 120 positioned on the substrate 110 and with the p-type layers 140 positioned adjacent to the contact 160, with the one or more quantum wells 130 positioned between the n-type layers 120 and the p-type layers 140. In some embodiments of the present disclosure, the polarity of an LED 100 may be reversed. Specifically, in some embodiments of the present disclosure, the p-type layers may be positioned on a substrate, with the n-type layers positioned adjacent to a contact, and with the one or more quantum wells positioned between the n-type layers and the p-type layers.

Referring again to FIG. 1B, a two-junction LED 100B is illustrated having a first device stack 105A and a second device stack 105B, with each device stack (105A and 105B) having the same features as those shown for the single device stack 105 of the single-junction LED 100A illustrated in FIG. 1A, with the additional feature being a tunnel junction 170 positioned between the first device stack 105A and the second device stack 105B, leading to the following device architecture: substrate 110/first device stack 105A/tunnel junction 170/second device stack 105B/contact 160. Similarly, a three-junction LED will have three device stacks (not shown) and two tunnel junctions, with the following device architecture: substrate/first device stack/first tunnel junction/second device stack/second tunnel junction/third device stack/contact. In some embodiments of the present disclosure an LED may have between 1 junction and 10 junctions, i.e., between 1 and 10 device stacks. Thus, the number of junctions, x, equals the number of device stacks and the corresponding number of tunnel junctions is equal to x−1.

In some embodiments of the present disclosure, the design of the multiple device stacks 105 making up a multi-junction LED 100 may be the same, e.g., using the same compositions, thicknesses, bandwidths, etc., with each device stack producing the same emission spectrum. However, in some embodiments of the present disclosure, the design of the multiple device stacks 105 making up a multi-junction LED 100 may be different; e.g., using at least one different composition, thickness, bandwidth, etc., resulting in the production of more than one emission spectrum. The specific design and number of junctions used in a particular LED will depend on its specific application and intended use.

Panel A of FIG. 1C illustrates a tunnel junction 170, according to some embodiments of the present disclosure. The tunnel junction 170 may be positioned between the p-type layers 140A of a first neighboring device stack 105A (not shown) and the n-type layers 120B of a second neighboring device stack 105B (not shown), as shown in FIG. 1B. In this example, the tunnel junction 170 is a highly-doped p-n junction constructed using three distinct layers, a highly doped p-layer (second layer 170-2), a highly doped n-layer (third layer 170-3), and between them a highly doped n-layer with lower bandgap (first layer 170-1). The doping in these layers may be high enough to enable efficient tunneling transport across the p-n junction, about 1e19 cm⁻³. The lower bandgap first layer 170-1 is not required by all tunnel junctions but may be used to facilitate tunneling transport. Among other things, an important feature of a tunnel junction 170 is that it be transparent to the light being emitted by the LED 100.

Panel B of FIG. 1C illustrates one or more quantum wells 130, according to some embodiments of the present disclosure, as illustrated in FIG. 1A. In some embodiments of the present disclosure, the one or more quantum wells 130 may be positioned between the n-type layers 120 and the p-type layers 140 of a single device stack 100A, as shown in FIGS. 1A and 1B. A device stack 100 may include between 1 and 100 quantum wells positioned in series, with each individual quantum well constructed of three layers, a well layer positioned between two barrier layers. Referring again to Panel B of FIG. 1C, an exemplary quantum well 130-1 is illustrated, constructed of a well layer 130-1 positioned between a first barrier layer 130-2 and a second barrier layer 130-3. In some embodiments of the present disclosure, for each quantum well 130, the well layer, the first barrier layer, and the second barrier layer may be strain-balanced. In some embodiments of the present disclosure, a device stack 100 may include between 1 and 50 quantum wells positioned between the n-type layers 120 and the p-type layers 140. In some embodiments of the present disclosure, a device stack 100 may include between 1 and 20 quantum wells positioned between the n-type layers 120 and the p-type layers 140. In some embodiments of the present disclosure, a device stack 100 may include 15 quantum wells positioned between the n-type layers 120 and the p-type layers 140.

In some embodiments of the present disclosure, an LED 100 may be constructed using III-V alloys such that the LED 100 is capable of emitting light having a wavelength between 880 nm and 1300 nm. In some embodiments of the present disclosure, an n-type outer barrier layer 126 may be constructed using at least one of GaAs, AlGaAs, GaInP, AlGaInP, GaInAsP and/or GaP. In some embodiments of the present disclosure, an n-type outer barrier layer 126 may be constructed of GaAs except for dopants such as Si, Se, or Te with about 1e17 cm⁻³ concentration. In some embodiments of the present disclosure, a p-type outer barrier layer 142 may be constructed using at least one of GaAs AlGaAs, GaInP, AlGaInP, GaInAsP and/or GaP. In some embodiments of the present disclosure, a p-type outer barrier layer 142 may be constructed of GaAs except for dopants such as C, Zn, and/or Mg with about 1e17 cm⁻³ concentration. An n-type outer barrier layer 126 may have a thickness between 20 nm and 1000 nm or between 20 nm and 200 nm. A p-type outer barrier layer 142 may have a thickness between 20 nm and 1000 nm or between 20 nm and 200 nm.

In some embodiments of the present disclosure, an n-type cladding layer 124 may be constructed using an alloy such as at least one of GaInP, AlGaAs, GaInAsP, and/or AlGaInP. In some embodiments of the present disclosure, an n-type cladding layer 124 may be constructed using an alloy that includes Ga₁₋ᵥInᵥP, where 0.4≤v≤0.6. In some embodiments, v may be equal to about 0.5. An n-type cladding layer 124 may be characterized by a bandgap that is greater than about 1.4 eV. An n-type cladding layer 124 may have a thickness between 20 nm and 1000 nm or between 20 nm and 200 nm. In some embodiments of the present disclosure, a p-type cladding layer 144 may be constructed using an alloy such as at least one of GaInP, AlGaAs, GaInAsP, and/or AlGaInP. In some embodiments of the present disclosure, a p-type cladding layer 144 may be constructed using an alloy that includes Ga₁₋ᵥInᵥP, where 0.4≤v≤0.6. In some embodiments, v may be equal to about 0.5. A p-type cladding layer 144 may be characterized by a bandgap that is greater than about 1.4 eV. A p-type cladding layer 144 may have a thickness between 20 nm and 1000 nm or between 20 nm and 200 nm. The cladding layers confine carriers to the active region, and may have a higher bandgap than the light emitting layers (e.g., including barrier layers and quantum wells). Dopant concentrations in the cladding layers may be about 1e18 cm⁻³.

A barrier layer defines the quantum well regions. A barrier layer may have a larger bandgap energy than the quantum well layer and ideally a type I alignment with the quantum well layer. Referring again to FIG. 1C, in some embodiments of the present disclosure, a barrier layer (reference numerals 130-2 and/or 130-3) of a quantum well 130 may be constructed of an alloy that includes GaAs_{1-w}P_{w}, where 0.01<w<0.4 or 0.01≤w≤0.5. In some embodiments w may be equal to about 0.1. In some embodiments of the present disclosure, a barrier layer 130-2 and/or 130-3 may have a thickness between 1 nm and 50 nm or between 1 nm and 25 nm. In some embodiments of the present disclosure, a barrier layer (130-2 and/or 130-3) may have a thickness that is about 8.5 nm. Referring again to FIG. 1C, in some embodiments of the present disclosure, a well layer 130-1 of a quantum well 130 may be constructed of an alloy that includes GaIn₁₋ₓAsₓ, where 0.01<x<0.4 or 0.01≤x≤0.2. In some embodiments x may be equal to about 0.1. In some embodiments of the present disclosure, a well layer 130-1 may have a thickness between 1 nm and 50 nm or between 1 nm and 25 nm. In some embodiments of the present disclosure, a well layer 130-1 may have a thickness that is about 8.5 nm. The quantum wells and barriers may be doped and/or undoped. In some embodiments of the present disclosure, the quantum wells and barriers are undoped. The alloy composition and bandgap of the quantum well determines the emission wavelength.

In some embodiments of the present disclosure, the layers 170-2 and/or 170-3 of a tunnel junction 170 may be constructed of GaAs. The layer 170-1 of a tunnel junction 170 may have a thickness between 3 nm and 20 nm. In some embodiments of the present disclosure, the layers 170-2 and 170-3 of a tunnel junction 170 may be constructed of a first p-type alloy that includes Al_{1-y}Ga_{y}As and a second n-type alloy that includes Al_{1-y}Ga_{y}As, where 0<y<1 or 0.2≤y≤1. In some embodiments, y may be equal to about 0.6. In some embodiments of the present disclosure, the layers 170-2 and 170-3 of a tunnel junction 170 may be heavily doped to about 1e19 cm⁻³.

In some embodiments of the present disclosure, an LED device like those described herein may further include a feature such as at least one of an antireflection coating and/or a textured surface to enhance light emission.

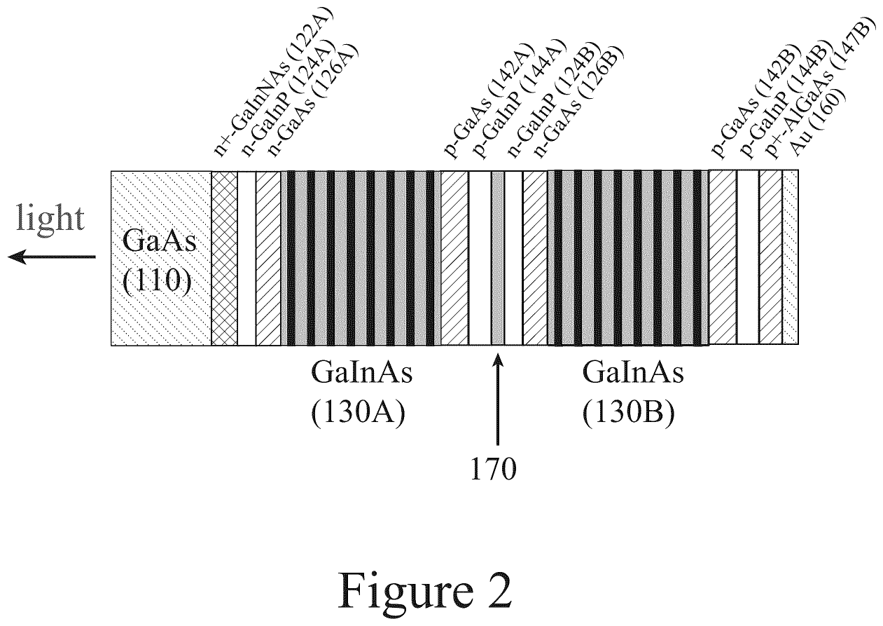

Three light emitting devices were designed with one, two, or four junctions. An illustration of the structure of an example structure 2-junction device is shown in FIG. 2. The direction of the emitted light is indicated in FIG. 2. However, depending on the device architecture, light may be emitted in essentially any direction.

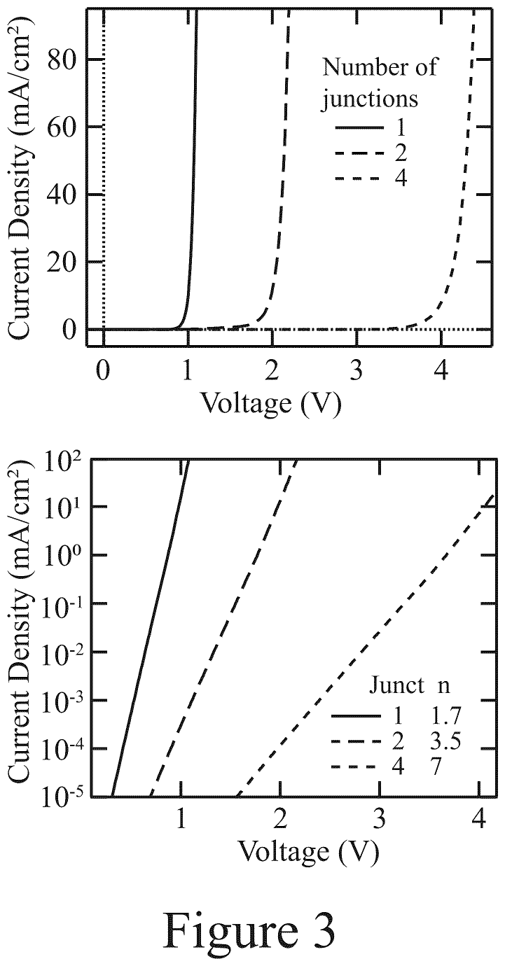

Dark IV curves are shown in FIG. 3. An increase in the turn-on voltage, and thus operating voltage, can be observed. In addition, the ideality factors of 1, 2, and 4 junction devices are equivalent per number of junctions in the device, showing no major loss mechanisms in the multijunction devices.

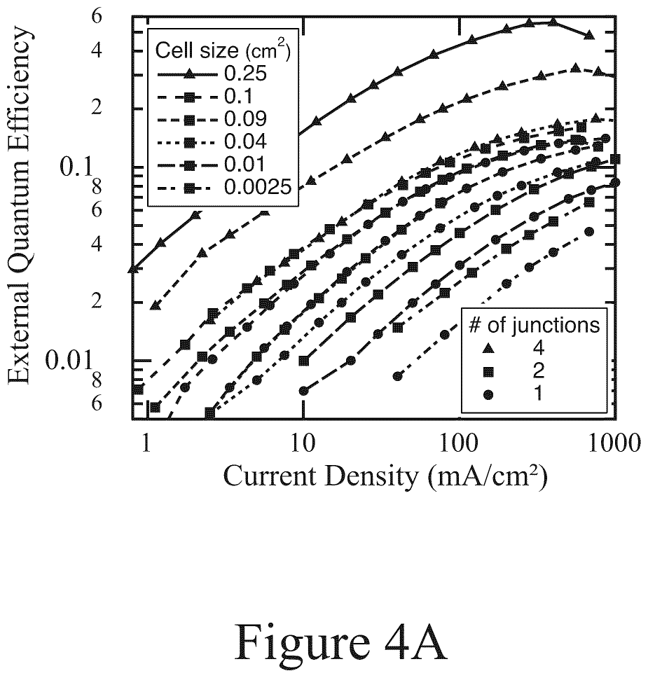

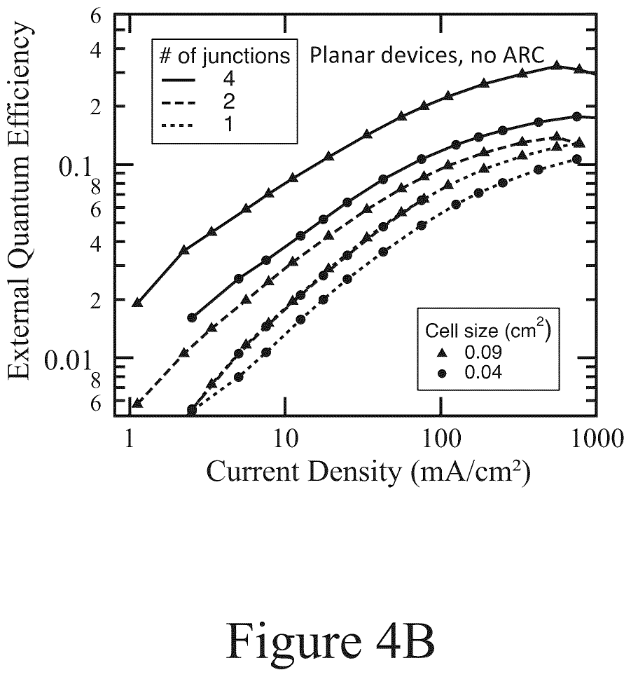

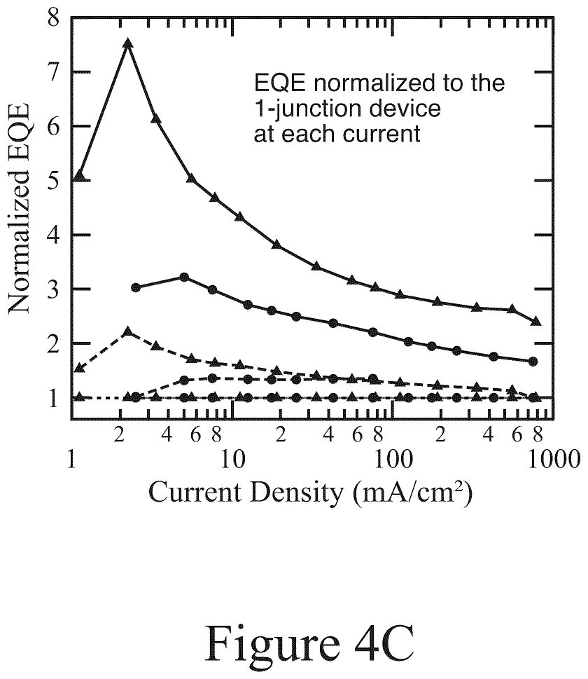

Radiative efficiency, also called external quantum efficiency (EQE) or external radiative efficiency, is shown in FIGS. 4A, 4B, and 4C. A variety of cell sizes were tested. However, for each size, some level of EQE addition is observed, showing that multijunction LEDs emit more photons for a given current than single junction devices.

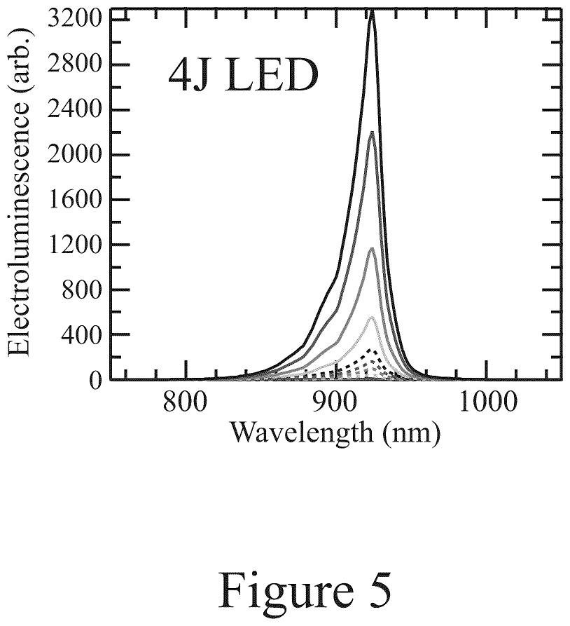

FIG. 5 illustrates the electroluminescence versus wavelength for a four-junction device, according to some embodiments of the present disclosure.

### EXAMPLES

Example 1. A device comprising: a tunnel junction; and a first stack and a second stack, each stack comprising, in order: an n-type cladding layer comprising an alloy selected from the group consisting of GaInP, AlGaAs, GaInAsP, and AlGaInP; an n-type outer barrier layer comprising at least one of GaAs or GaP; at least one quantum well; a p-type outer barrier layer comprising at least one of GaAs or GaP; and a p-type cladding layer comprising an alloy selected from the group consisting of GaInP, AlGaAs, GaInAsP, and AlGaInP, wherein: the tunnel junction is positioned between the p-type cladding layer of the first stack and the n-type cladding layer of the second stack, the device is capable of emitting light having a wavelength between 880 nm and 1300 nm, and the tunnel junction is transparent to the emitted light.

Example 2. The device of Example 1, wherein the n-type outer barrier layer and p-type outer barrier layer are GaAs.

Example 3. The device of either Example 1 or Example 2, wherein the n-type cladding layer comprises Ga₁₋ᵥInᵥP and 0≤v≤1.0.

Example 4. The device of any one of Examples 1-3, wherein 0.4≤v≤0.6.

Example 5. The device of any one of Examples 1-4, wherein v is about equal to 0.5.

Example 6. The device of any one of Examples 1-5, wherein the n-type cladding layer has a bandgap greater than about 1.4 eV.

Example 7. The device of any one of Examples 1-6, wherein the p-type cladding layer comprises Ga₁₋ᵥInᵥP.

Example 8. The device of any one of Examples 1-7, wherein 0.4≤v≤0.6.

Example 9. The device of any one of Examples 1-8, wherein v is about equal to 0.5.

Example 10. The device of any one of Examples 1-9, wherein the n-type cladding layer has a bandgap greater than about 1.4 eV.

Example 11. The device of any one of Examples 1-10, wherein the n-type cladding layer has a thickness between 20 nm and 1000 nm.

Example 12. The device of any one of Examples 1-11, wherein the n-type cladding layer has a thickness between 20 nm and 200 nm.

Example 13. The device of any one of Examples 1-12, wherein the p-type cladding layer has a thickness between 20 nm and 1000 nm.

Example 14. The device of any one of Examples 1-13, wherein the p-type cladding layer has a thickness between 20 nm and 200 nm.

Example 15. The device of any one of Examples 1-14, wherein the n-type outer barrier layer has a thickness between 20 nm and 1000 nm.

Example 16. The device of any one of Examples 1-15, wherein the n-type outer barrier layer has a thickness between 20 nm and 200 nm.

Example 17. The device of any one of Examples 1-16, wherein the p-type outer barrier layer has a thickness between 20 nm and 1000 nm.

Example 18. The device of any one of Examples 1-17, wherein the p-type outer barrier layer has a thickness between 20 nm and 200 nm.

Example 19. The device of any one of Examples 1-18, wherein each quantum well comprises a well layer positioned between a first barrier layer and a second barrier layer.

Example 20. The device of any one of Examples 1-19, wherein for each quantum well, the well layer, the first barrier layer, and the second barrier layer are strain-balanced.

Example 21. The device of any one of Examples 1-20, wherein the number of quantum wells is between 1 and 50 inclusively.

Example 22. The device of any one of Examples 1-21, wherein the number of quantum wells is between 1 and 20 inclusively.

Example 23. The device of any one of Examples 1-22, wherein the number of quantum wells is 15.

Example 24. The device of any one of Examples 1-23, wherein each barrier layer comprises GaAs_{1-w}P_{w} and 0.01<w<0.5.

Example 25. The device of any one of Examples 1-24, wherein 0.01≤w≤0.4.

Example 26. The device of any one of Examples 1-25, wherein w is about equal to about 0.1.

Example 27. The device of any one of Examples 1-26, wherein the well layer has a thickness between 1 nm and 50 nm.

Example 28. The device of any one of Examples 1-27, wherein the well layer has a thickness between 1 nm and 25 nm.

Example 29. The device of any one of Examples 1-28, wherein the well layer has a thickness of about 17 nm.

Example 30. The device of any one of Examples 1-29, wherein each well layer comprises GaIn₁₋ₓAsₓ and 0.01≤x≤0.4.

Example 31. The device of any one of Examples 1-30, wherein 0.01≤x≤0.2.

Example 32. The device of any one of Examples 1-31, wherein x is equal to about 0.1.

Example 33. The device of any one of Examples 1-32, wherein each barrier layer has a thickness between 1 nm and 50 nm.

Example 34. The device of any one of Examples 1-33, wherein each barrier layer has a thickness between 1 nm and 25 nm.

Example 35. The device of any one of Examples 1-34, wherein each barrier layer has a thickness of about 8.5 nm.

Example 36. The device of any one of Examples 1-35, wherein the tunnel junction comprises a heavily doped p-n junction.

Example 37. The device of any one of Examples 1-36, wherein the tunnel junction further comprises a quantum well.

Example 38. The device of any one of Examples 1-37, wherein the quantum well of the tunnel junction comprises GaAs.

Example 39. The device of any one of Examples 1-38, wherein the quantum well of the tunnel junction has a thickness between 3 nm and 20 nm.

Example 40. The device of any one of Examples 1-39, wherein the p-n junction comprises p-type Al_{1-y}Ga_{y}As and n-type Al_{1-y}Ga_{y}As and 0<y<1.

Example 41. The device of any one of Examples 1-40, wherein 0.2≤y≤1.

Example 42. The device of any one of Examples 1-41, wherein y is equal to about 0.6.

Example 43. The device of any one of Examples 1-42, further comprising at least one additional stack.

Example 44. The device of any one of Examples 1-43, comprising three stacks.

Example 45. The device of any one of Examples 1-44, comprising four stacks.

Example 46. The device of any one of Examples 1-45, further comprising an antireflective layer or a textured surface.

The foregoing discussion and examples have been presented for purposes of illustration and description. The foregoing is not intended to limit the aspects, embodiments, or configurations to the form or forms disclosed herein. In the foregoing Detailed Description for example, various features of the aspects, embodiments, or configurations are grouped together in one or more embodiments, configurations, or aspects for the purpose of streamlining the disclosure. The features of the aspects, embodiments, or configurations, may be combined in alternate aspects, embodiments, or configurations other than those discussed above. This method of disclosure is not to be interpreted as reflecting an intention that the aspects, embodiments, or configurations require more features than are expressly recited in each claim. Rather, as the following claims reflect, inventive aspects lie in less than all features of a single foregoing disclosed embodiment, configuration, or aspect. While certain aspects of conventional technology have been discussed to facilitate disclosure of some embodiments of the present invention, the Applicants in no way disclaim these technical aspects, and it is contemplated that the claimed invention may encompass one or more of the conventional technical aspects discussed herein. Thus, the following claims are hereby incorporated into this Detailed Description, with each claim standing on its own as a separate aspect, embodiment, or configuration.

What is claimed is:

1. A device comprising:
a tunnel junction; and
a first stack and a second stack, each stack comprising, in order:
an n-type cladding layer comprising an alloy selected from the group consisting of GaInP, AlGaAs, GaInAsP, and AlGaInP;
an n-type outer barrier layer comprising at least one of GaAs or GaP;
at least one quantum well;
a p-type outer barrier layer comprising at least one of GaAs or GaP; and
a p-type cladding layer comprising an alloy selected from the group consisting of GaInP, AlGaAs, GaInAsP, and AlGaInP, wherein:
the tunnel junction is positioned between the p-type cladding layer of the first stack and the n-type cladding layer of the second stack,
the device is capable of emitting light having a wavelength between 880 nm and 1300 nm, and
the tunnel junction is transparent to the emitted light.

2. The device of claim 1, wherein the n-type outer barrier layer and p-type outer barrier layer are GaAs.

3. The device of claim 1, wherein the n-type cladding layer comprises Ga₁₋ᵥInᵥP and
$$0 < v < 1. .$$

4. The device of claim 3, wherein 0.4≤v≤0.6.

5. The device of claim 1, wherein the n-type cladding layer has a bandgap greater than about 1.4 eV.

6. The device of claim 1, wherein the p-type cladding layer comprises Ga₁₋ᵥInᵥP and
$$0 \leq v \leq 1. .$$

7. The device of claim 6, wherein 0.4≤v≤0.6.

8. The device of claim 7, wherein v is about equal to 0.5.

9. The device of claim 1, wherein the n-type cladding layer has a bandgap greater than about 1.4 eV.

10. The device of claim 1, wherein each quantum well comprises a well layer positioned between a first barrier layer and a second barrier layer.

11. The device of claim 10, wherein for each quantum well, the well layer, the first barrier layer, and the second barrier layer are strain-balanced.

12. The device of claim 1, wherein the number of quantum wells is between 1 and 50 inclusively.

13. The device of claim 10, wherein each barrier layer comprises GaAs_{1-w}P_{w} and
$$0.01 < w < 0.5 .$$

14. The device of claim 10, wherein each well layer comprises GaIn₁₋ₓAsₓ and 0.01<x<0.4.

15. The device of claim 1, wherein the tunnel junction comprises a heavily doped p-n junction.

16. The device of claim 15, wherein the tunnel junction further comprises a quantum well.

17. The device of claim 16, wherein the quantum well of the tunnel junction comprises GaAs.

18. The device of claim 16, wherein the quantum well of the tunnel junction has a thickness between 3 nm and 20 nm.

19. The device of claim 15, wherein the p-n junction comprises p-type Al_{1-y}Ga_{y}As and n-type Al_{1-y}Ga_{y}As and 0<y<1.

20. The device of claim 1, further comprising at least one additional stack.
